(19) United States
(12) Patent Application Publication
(10) Pub. No.: US 2022/0277940 A1
(43) Pub. Date: Sep. 1, 2022

(54) METHOD AND APPARATUS FOR SPUTTER DEPOSITION

(71) Applicant: Dyson Technology Limited, Wiltshire (GB)

(72) Inventor: Michael Edward RENDALL, Newbury (GB)

(73) Assignee: Dyson Technology Limited, Wiltshire (GB)

(21) Appl. No.: 17/774,421

(22) PCT Filed: Nov. 10, 2020
(86) PCT No.: PCT/GB2020/052841

§ 371 Date: May 4, 2022

(30) Foreign Application Priority Data
Nov. 15, 2019 (GB) 1916637.0

(51) Int. Cl. H01J 37/34; H01J 37/32; C23C 14/35; C23C 14/56

(52) U.S. Cl. CPC H01J 37/3402; H01J 37/3211; H01J 37/3458; H01J 37/3417; H01J 37/3444; C23C 14/35; C23C 14/562; H01J 2237/332

(57) ABSTRACT

Apparatus for sputter deposition of target material to a substrate is disclosed. In one form, the apparatus includes a substrate guide arranged to guide a substrate along a curved path and a target portion spaced from the substrate guide and arranged to support target material. The target portion and the substrate guide define between them a deposition zone. The apparatus includes biasing element for applying electrical bias to the target material. The apparatus also includes a confining arrangement including one or more magnetic elements arranged to provide a confining magnetic field to confine plasma in the deposition zone thereby to provide for sputter deposition of target material to the web of substrate in use. The confining magnetic field having magnetic field lines arranged to, at least in the deposition zone, substantially follow a curve of the curved path so as to confine said plasma around said curve of the curved path.

### TECHNICAL FIELD

The present invention relates to deposition, and more particularly to methods and apparatuses for sputter deposition of target material to a substrate.

### BACKGROUND

Deposition is a process by which target material is deposited on a substrate. An example of deposition is thin film deposition in which a thin layer (typically from around a nanometre or even a fraction of a nanometre up to several micrometres or even tens of micrometres) is deposited on a substrate, such as a silicon wafer or web. An example technique for thin film deposition is Physical Vapor Deposition (PVD), in which target material in a condensed phase is vaporised to produce a vapor, which vapor is then condensed onto the substrate surface. An example of PVD is sputter deposition, in which particles are ejected from the target as a result of bombardment by energetic particles, such as ions. In examples of sputter deposition, a sputter gas, such as an inert gas, such as argon, is introduced into a vacuum chamber at low pressure, and the sputter gas is ionised using energetic electrons to create a plasma. Bombardment of the target by ions of the plasma eject target material which may then deposit on the substrate surface. Sputter deposition has advantages over other thin film deposition methods such as evaporation in that target materials may be deposited without the need to heat the target material, which may in turn reduce or prevent thermal damage to the substrate.

A known sputter deposition technique employs a magnetron, in which a glow discharge is combined with a magnetic field that causes an increase in plasma density in a circular shaped region close to the target. The increase of plasma density can lead to an increased deposition rate. However, use of magnetrons results in a circular “racetrack” shaped erosion profile of the target, which limits the utilisation of the target and can negatively affect the uniformity of the resultant deposition.

It is desirable to provide uniform, controllable and/or efficient sputter deposition to allow for improved utility in industrial applications.

### SUMMARY

According to a first aspect of the present invention, there is provided a sputter deposition apparatus comprising:

a substrate guide arranged to guide a substrate along a curved path;

a target assembly comprising:
a target portion spaced from the substrate guide and arranged to support target material, the target portion and the substrate guide defining between them a deposition zone; and
biasing means for applying electrical bias to the target material; and

a confining arrangement comprising one or more magnetic elements arranged to provide a confining magnetic field to confine plasma in the deposition zone thereby to provide for sputter deposition of target material to the substrate in use, the confining magnetic field being characterised by magnetic field lines arranged to, at least in the deposition zone, substantially follow a curve of the curved path so as to confine said plasma around said curve of the curved path.

By guiding the substrate along the curved path, the apparatus for example provides for compact sputter deposition of a target material on a large surface area of a substrate in a “reel-to-reel” type system. A reel-to-reel deposition system may be more efficient than a batch process, which may involve ceasing deposition in between batches.

With the magnetic field lines substantially following the curve of the curved path, the plasma may be confined round the curve path into the deposition zone. The density of the plasma may therefore be more uniform in the deposition zone, at least in a direction around the curve of the curved path. This may increase the uniformity of the target material deposited on the substrate. The consistency of the processed substrate may therefore be improved, reducing the need for quality control.

Applying electrical bias to the target material results in ions from the plasma in the vicinity of the target material to be attracted to a region adjacent to the target material. This can increase the rate of interactions between the plasma ions and the target material, increasing the efficiency of sputter deposition. By controlling the electrical bias applied to the target material, the density of plasma ions adjacent to the target material can also be controlled. Accurate control of the plasma ions in this way may provide for patterned sputter deposition of the target material on a substrate, with a greater density of the target material deposited on a particular portion of the substrate, e.g. which overlaps the biased target material. This may be more efficient and less wasteful than deposition of a pattern of material on a substrate using a mask to protect areas of the substrate which are to remain uncoated. Moreover, the inventors have surprisingly found that the crystallinity of the target material deposited on a substrate can be controlled by appropriately controlling the electrical bias applied to the target material. In this way, target material with a desired crystallinity can be straightforwardly sputter deposited on a substrate.

In examples, the biasing means is configured to apply electrical bias having negative polarity to the target material. This can be used to attract positive ions from the plasma towards the target material, to increase the rate of sputter deposition.

In examples, the biasing means is configured to apply electrical bias comprising a direct current voltage to the target material. This may increase the uniformity of the sputter deposition compared to applying an alternating current voltage to the target material.

In some examples, the apparatus further comprises a plasma generation arrangement configured to generate plasma. In certain cases, the biasing means is configured to apply the electrical bias to the target material at a first power value, and the plasma generation arrangement is configured to generate the plasma at a second power value, such that a ratio of the second power value to the first power value is greater than 1. With the ratio of the second power value to the first power value being greater than 1, the target material sputter deposited on a substrate tends to have a structure that is at least partially ordered. This structure may be obtained irrespective of the substrate onto which the target material is sputter deposited, meaning that an apparatus arranged in this way has utility for sputter deposition of at least partially ordered materials, such as crystalline materials, on a wide range of different substrates.

In some cases, the ratio of the second power value to the first power value is less than 3.5 or less than 1.5. Such ratios may be aid in depositing the target material with an at least partially ordered structure without annealing the deposited target material. This can simplify the deposition of materials with such a structure.

The first power value is at least one watt per square centimetre, 1 W cm⁻² in examples. This first power value has been found to be effective in order for sputtering of the target material to occur.

In some cases, the first power value is at most fifteen watts per square centimetre, 15 W cm⁻², or at most seventy watts per square centimetre, 70 W cm⁻². For example, a first power value of up to 15 W cm⁻² may be suitable for target materials comprising ceramic and/or oxide, whereas a first power value of up to 70 W cm⁻² metallic target materials comprising lithium, cobalt or alloys of lithium and/or cobalt.

In examples, the target portion is arranged to support plural target materials and the biasing means is configured to apply electrical bias independently to one or more respective target materials of the plural target materials. This improves the flexibility of the apparatus. For example, by controlling the electrical bias associated with different respective target materials, deposition of the different target materials may in turn be controlled. In this way, the apparatus may be used to deposit a greater quantity of one of the plural target materials than another, e.g. to deposit a desired combination of target materials on a substrate. Further, applying electrical bias independently to one or more respective target materials may provide further flexibility for the deposited of a desired pattern of target material on a substrate, e.g. by controlling the relative electrical bias applied to each of the target materials to deposit more or less from each.

In examples, the apparatus further comprises a plasma generation arrangement arranged to generate plasma, and the plasma generation arrangement comprises an inductively coupled plasma source. An inductively coupled plasma source may be easily controlled, allowing the sputter deposition itself to be controlled straightforwardly.

In examples, the plasma generation arrangement comprises one or more elongate antennae that extend in a direction substantially perpendicular to a longitudinal axis of the substrate guide. In other examples, the plasma generation arrangement comprises one or more elongate antennae that extend in a direction substantially parallel to a longitudinal axis of the substrate guide. Irrespective of the direction in which the elongate antennae extend, the use of elongate antennae may provide for generation of plasma along the length of the antennae, which may allow an increased area of the substrate and/or target material to be exposed to the plasma. This may increase the efficiency of sputter deposition and may alternatively or additionally provide for more uniform deposition of the target material on the substrate.

In examples, the one or more magnetic elements are arranged to provide the confining magnetic field so as to confine plasma in the form of a curved sheet. By confining the plasma in the form of a curved sheet, an increased area of the substrate may be exposed to the plasma. The sputter deposition may therefore be performed over a larger surface area of the substrate, which may improve the efficiency of the sputter deposition. By providing a curved sheet of plasma, the density of the plasma can be more uniform. In some cases, the uniformity of the plasma is increased around the curve of the curved path and over the width of the substrate. This can allow for more uniform sputter deposition of the target material onto the substrate.

In examples, the one or more magnetic elements are arranged to provide the confining magnetic field so as to confine plasma in the form of a curved sheet having, at least in the deposition zone, a substantially uniform density. With a substantially uniform density of plasma in the deposition zone, the target material may be deposited on the substrate with a substantially uniform thickness. This may improve the consistency of the substrate after deposition and reduce the need for quality control.

In examples, one or more of the magnetic elements is an electromagnet. Using an electromagnet allows the strength of the confining magnetic field to be controlled. For example, in some cases the apparatus comprises a controller arranged to control the magnetic field provided by one or more of the electromagnets. In this way, a density of the plasma in the deposition zone may be adjusted, which may be used to adjust deposition of the target material on the substrate. Hence, control over the sputter deposition may be improved, improving the flexibility of the apparatus.

In examples, the confining arrangement comprises at least two of the magnetic elements arranged to provide the confining magnetic field. This may allow for more precise confinement of the plasma, and/or may allow for a greater degree of freedom in control of the confining magnetic field. For example, having at least two magnetic elements may increase an area of the substrate that is exposed to the plasma and hence increase an area of the substrate on which the target material is deposited. This may improve the efficiency of the sputter deposition process. In these examples, the at least two magnetic elements may be arranged such that a region of relatively high magnetic field strength provided between the magnetic elements substantially follows the curve of the curved path. This may increase the uniformity of the plasma around the curve of the curved path, which in turn may increase the uniformity of the target material sputter deposited on the substrate.

In examples, the target portion is arranged, or is configurable to be arranged, such that at least one part of the target portion defines a supporting surface forming an obtuse angle with respect to a supporting surface of another part of the target portion. This may allow for an increased area in which sputter deposition may be effected, but without increasing the spatial footprint of the target portion and without altering the curved path. This may increase the efficiency of the sputter deposition.

In examples, the target portion is substantially curved. This may increase a surface area of the target portion exposed to the substrate within the deposition zone, which may increase the efficiency with which the sputter deposition may be effected, and may be more compact than other arrangements.

In examples, the target portion is arranged to substantially follow or approximate the curve of the curved path. This may improve the uniformity with which the target material of the target portion is sputter deposited on the substrate, along the curve of the curved path. This may reduce the need for quality control.

In examples, the substrate guide is provided by a curved member that guides the substrate along the curved path. The substrate may be guided by rotation of the curved member, which may be a roller or drum. In this way, the apparatus may form part of a “reel-to-reel” process arrangement, which may process a substrate more efficiently than a batch processing arrangement.

According to a second aspect of the present invention, there is provided a method of sputter deposition of target material to a substrate, the substrate being guided by a substrate guide along a curved path, wherein a deposition zone is defined between the substrate guide and a target portion supporting target material, the method comprising:

applying electrical bias to the target material; and

providing a magnetic field to confine plasma in the deposition zone thereby to cause sputter deposition of target material to the substrate, the magnetic field being characterised by magnetic field lines arranged to, at least in the deposition zone, substantially follow a curve of the curved path so as to confine said plasma around the curved path.

This method may increase the uniformity of the plasma around the curve of the curved path, which may in turn increase the uniformity of the target material deposited on the substrate. By using the curved path, the method may be implemented as a reel-to-reel type process, which may be performed more efficiently than batch processes. Furthermore, by applying the electrical bias to the target material, the sputter deposition efficiency may be increased. The crystallinity of the target material deposited on the substrate may also or instead be controlled by the application of the electrical bias to the target material. Alternatively or additionally, control of the electrical bias may be used to control a pattern of target material deposited on the substrate, to deposit a desired pattern in a straightforward, efficient manner.

In some cases, the method includes providing the target material comprising at least one of lithium, cobalt, lithium oxide, cobalt oxide, and lithium cobalt oxide. These target materials may be used to manufacture various different devices, products or components.

In some examples, applying the electrical bias to the target comprises applying the electrical bias at a first power value, and the method comprises generating a plasma at a second power value, such that a ratio of the second power value to the first power value is greater than 1. Such a ratio may be used to deposit the target material on the substrate with an at least partially ordered structure. This may be more straightforward than other deposition processes, e.g. those that include post-processing such as annealing.

Further features will become apparent from the following description, given by way of example only, which is made with reference to the accompanying drawings.

### BRIEF DESCRIPTION OF THE DRAWINGS

FIG. 1 is a schematic diagram that illustrates a cross section of an apparatus according to an example;

FIG. 2 is a schematic diagram that illustrates a cross section of the example apparatus of FIG. 1, but including illustrative magnetic field lines;

FIG. 3 is a schematic diagram that illustrates a plan view of a portion of the example apparatus of FIGS. 1 and 2;

FIG. 4 is a schematic diagram that illustrates a plan view of the portion of the example apparatus of FIG. 3, but including illustrative magnetic field lines;

FIG. 5 is a schematic diagram that illustrates a cross section of a magnetic element according to an example;

FIG. 6 is a schematic diagram that illustrates a cross section of an apparatus according to an example;

FIG. 7 is a schematic diagram that illustrates a cross section of an apparatus according to an example;

FIG. 8 is a schematic diagram that illustrates a perspective view of an apparatus according to an example; and

FIG. 9 is a schematic flow diagram that illustrates a method according to an example.

### DETAILED DESCRIPTION

Details of apparatuses and methods according to examples will become apparent from the following description, with reference to the Figures. In this description, for the purpose of explanation, numerous specific details of certain examples are set forth. Reference in the specification to “an example” or similar language means that a particular feature, structure, or characteristic described in connection with the example is included in at least that one example, but not necessarily in other examples. It should further be noted that certain examples are described schematically with certain features omitted and/or necessarily simplified for ease of explanation and understanding of the concepts underlying the examples.

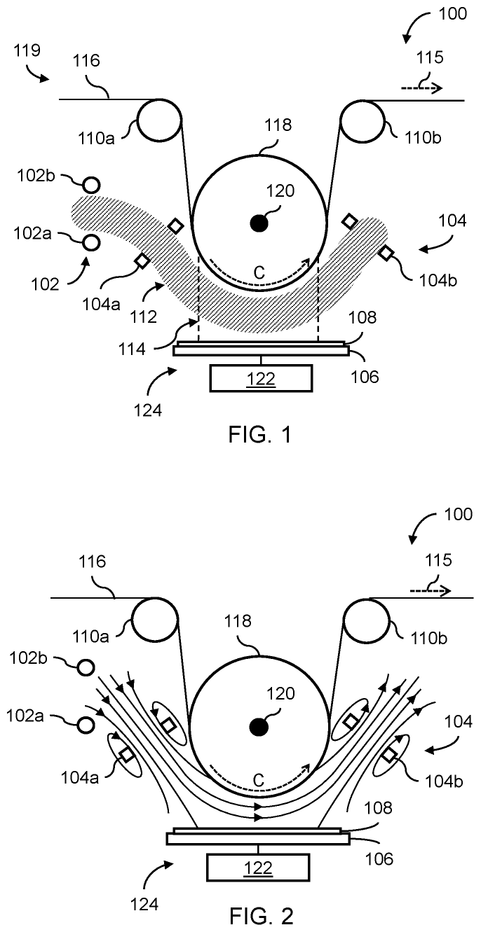

Referring to FIGS. 1 to 5, an example apparatus 100 for sputter deposition of target material 108 to a substrate 116 is illustrated.

The apparatus 100 may be used for plasma-based sputter deposition for a wide number of industrial applications, such as those which have utility for the deposition of thin films, such as in the production of optical coatings, magnetic recording media, electronic semiconductor devices, LEDs, energy generation devices such as thin-film solar cells, and energy storage devices such as thin-film batteries. Other applications for which the apparatus 100 may be used include the production of display devices such as OLED (organic light emitting diode), electroluminescent (ELD) or plasma display panel (PDP), high-performance addressing (HDP) liquid crystal display (LCD), or interferometric modulator display (IMOD) display devices, transistors such as thin-film transistors (TFTs), barrier coatings, dichroic coatings, or metallised coatings. Therefore, while the context of the present disclosure may in some cases relate to the production of energy storage devices or portions thereof, it will be appreciated that the apparatus 100 and method described herein are not limited to the production thereof.

Although not shown in the Figures for clarity, in some examples, it is to be appreciated that the apparatus 100 typically includes a housing (not shown), which in use is evacuated to a low pressure suitable for sputter deposition, for example 3×10⁻³ torr. Such a housing may be evacuated by a pumping system (not shown) to a suitable pressure (for example less than 1×10⁻⁵ torr). In use, a process or sputter gas, such as argon or nitrogen, may be introduced into the housing using a gas feed system (not shown) to an extent such that a pressure suitable for sputter deposition is achieved, e.g. 3×10⁻³ torr.

Returning to the example illustrated in FIGS. 1 to 5, in broad overview, the apparatus 100 comprises a substrate guide 118, a target assembly 124, and a magnetic confining arrangement 104.

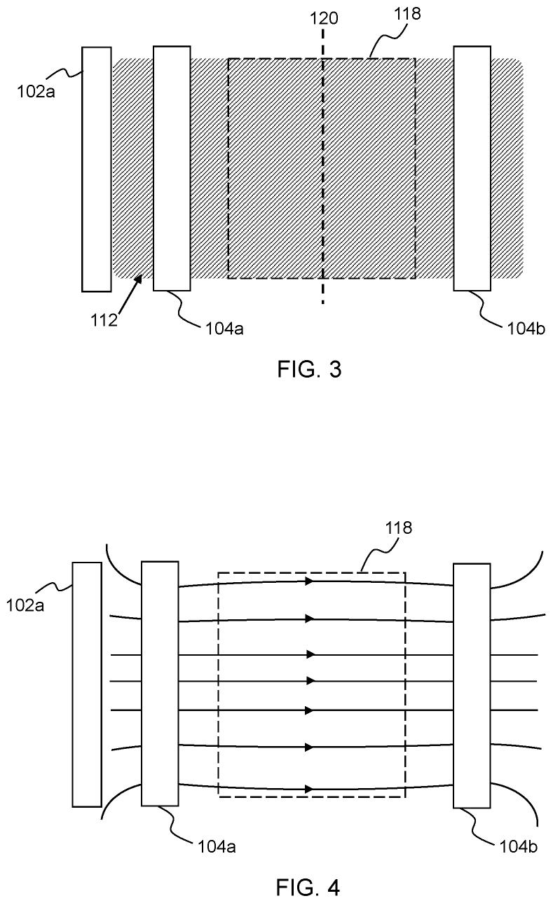

The substrate guide 118 is arranged to guide a substrate 116, e.g. a web of substrate, along a curved path (the curved path being indicated by arrow C in FIGS. 1 and 2).

In the example of FIGS. 1 and 2, the substrate guide 118 is provided by a curved member 118, which in this case is provided by a substantially cylindrical drum or roller of an overall substrate feed assembly 119. The curved member 118 of FIGS. 1 and 2 is arranged to rotate about an axis 120, for example provided by an axle. In the example illustrated in FIG. 3, the axis 120 is also a longitudinal axis of the curved member 118.

The substrate feed assembly 119 is arranged to feed the substrate 116 onto and from the curved member 118 such that the substrate 116 is carried by at least part of a curved surface of the curved member 118 (which in this case is formed by a drum 118). In some examples, such as that of FIGS. 1 and 2, the substrate feed assembly comprises a first roller 110a arranged to feed the substrate 116 onto the drum, and a second roller 110b arranged to feed the substrate 116 from the drum 118, after the substrate 116 has followed the curved path C. The substrate feed assembly 119 may be part of a “reel-to-reel” process arrangement (not shown), where the substrate 116 is fed from a first reel or bobbin (not shown) of substrate 116, passes through the apparatus 100, and is then fed onto a second reel or bobbin (not shown) to form a loaded reel of processed substrate (not shown).

In some examples, the substrate 116 is or at least comprises silicon or a polymer. In some examples, e.g. for the production of an energy storage device, the substrate 116 is or at least comprises nickel foil. It will be appreciated, however, that any suitable metal could be used instead of nickel, such as aluminium, copper or steel, or a metallised material including metallised plastics such as aluminium on polyethylene terephthalate (PET).

The target assembly 124 of the apparatus 100 includes a target portion 106 arranged to support target material 108. In some examples, the target portion 106 comprises a plate or other support structure that supports or holds the target material 108 in place during sputter deposition. The target material 108 is a material on the basis of which the sputter deposition onto the substrate 116 is to be performed. In other words, the target material 108 may be or comprise material that is to be deposited onto the substrate 116 by sputter deposition.

In some examples, e.g. for the production of an energy storage device, the target material 108 is or comprises (or is or comprises a precursor material for) a cathode layer of an energy storage device, such as a material which is suitable for storing lithium ions, e.g. lithium cobalt oxide, lithium iron phosphate or alkali metal polysulphide salts. Additionally, or alternatively, the target material 108 is or comprises (or is or comprises a precursor material for) an anode layer of an energy storage device, such as lithium metal, graphite, silicon or indium tin oxides. Additionally, or alternatively, the target material 108 is or comprises (or is or comprises a precursor material for) an electrolyte layer of an energy storage device, such as a material which is ionically conductive, but which is also an electrical insulator, e.g. lithium phosphorous oxynitride (LiPON). For example, the target material 108 is, or comprises, LiPO as a precursor material for the deposition of LiPON onto the substrate 116, e.g. via reaction with nitrogen gas in the region of the target material 108. In certain examples, the target material comprises at least one of: lithium, cobalt, lithium oxide, cobalt oxide and lithium cobalt oxide. For example, to deposit lithium cobalt oxide on a substrate, the target material may comprise lithium and cobalt, lithium oxide and cobalt, lithium oxide and cobalt oxide, a lithium-cobalt alloy, lithium cobalt oxide, or LiCoO₂₋ₓ, where x is greater than or equal to 0.01 or less than or equal to 1.99.

The target portion 106 and the substrate guide 118 are spaced apart from one another and define between them a deposition zone 114. The deposition zone 114 may be taken as the area or volume between the substrate guide 118 and the target portion 106 in which sputter deposition from the target material 108 onto the substrate 116 occurs in use.

In some examples, such as those illustrated, the apparatus 100 comprises a plasma generation arrangement 102, which may be referred to as a plasma source 102.

The plasma generation arrangement 102 is configured to generate plasma 112. The plasma source 102 may be an inductively coupled plasma source, e.g. arranged to generate an inductively coupled plasma 112. The plasma source 102 shown in FIGS. 1 and 2 includes antennae 102a, 102b, through which appropriate radio frequency (RF) power may be driven by a radio frequency power supply system (not shown) to generate an inductively coupled plasma 112 from the process or sputter gas in the housing (not shown). In some examples, plasma 112 is generated by driving a radio frequency current through the one or more antennae 102a, 102b, for example at a frequency between 1 MHz and 1 GHz; a frequency between 1 MHz and 100 MHz; a frequency between 10 MHz and 40 MHz; or, in some examples, at a frequency of approximately 13.56 MHz or multiples thereof. The RF power causes ionisation of the process or sputter gas to produce plasma 112. Tuning the RF power driven through the one or more antennae 102a, 102b can affect the plasma density of the plasma 112 within the deposition zone 114. Thus, by controlling the RF power at the plasma source 102, the sputter deposition process can be controlled. This in turn allows for improved flexibility in the operation of the sputter deposition apparatus 100.

In some examples, such as that of FIGS. 1 and 2, the plasma source 102 is disposed remotely of the substrate guide 118, e.g. radially away from the substrate guide 118. The plasma 112 generated by the plasma source 102 is nevertheless be guided towards and subsequently at least partly confined within the sputter deposition zone 114 between the substrate guide 118 and the target portion 106.

The one or more antennae 102a, 102b of the plasma source 102 may be elongate antennae, and in some examples are substantially linear. In some examples, such as that of FIGS. 1 and 2, the one or more antennae 102a, 102b are elongate antennae and extend in a direction substantially parallel to the longitudinal axis 120 of the curved member 108 (e.g. the axis 120 of the drum 118 which passes through the origin of the radius of curvature of the drum 118). One or more of the elongate antennae 102a, 102b may be curved. For example, such curved elongate antennae 102a, 102b may follow the curvature of a curved surface of the curved member 118. In some cases, one or more of the curved elongate antennae 102a, 102b extend in a plane substantially perpendicular to the longitudinal axis 120 of the curved member 118. This is discussed further with reference to FIG. 8, which illustrates such an example.

In the example of FIGS. 1 and 2, the plasma source 102 comprises two antennae 102a, 102b for producing an inductively coupled plasma 112. In this example, the antennae 102a, 102b extend substantially parallel to one another and are disposed laterally from one another. This allows for precise generation of an elongate region of plasma 112 between the two antennae 102a, 102b, which in turn helps provide for precise confining of the generated plasma 112 to at least the deposition zone 114, as described in more detail below. The antennae 120a, 120b may be similar in length to the substrate guide 118, and accordingly similar to the width of the substrate 116 guided by the substrate guide 118. The elongate antennae 102a, 102b can provide for plasma 112 to be generated across a region having a length corresponding to the length of the substrate guide 118 (and hence corresponding to the width of the substrate 116), and hence can allow for plasma 112 to be available evenly or uniformly across the width of the substrate 116. As described in more detail below, this in turn helps provide for even or uniform sputter deposition.

The confining arrangement 104 of the apparatus 100 of FIGS. 1 and 2 comprises one or more magnetic elements 104a, 104b. The magnetic elements 104a, 104b are arranged to provide a confining magnetic field to confine plasma 112 (which in this case includes the plasma generated by the plasma generation arrangement 102) in the deposition zone 114, in order to provide for sputter deposition of target material 108 to the substrate 116 in use. The confining magnetic field is characterised by magnetic field lines arranged to, at least in the deposition zone 114, substantially follow a curve of the curved path C so as to confine the plasma 112 around the curve of the curved path C.

It will be appreciated that magnetic field lines may be used to characterise or describe the arrangement or geometry of a magnetic field. As such it will be understood that the confining magnetic field provided by the magnetic elements 104a, 104b may be described or characterised by magnetic field lines arranged to follow a curve of the curved path C. It will also be appreciated that, in principle, the whole or entire magnetic field provided by the magnetic elements 104a, 104b may comprise portions that are characterised by magnetic field lines which are not arranged to follow the curve of the curved path C. Nonetheless, the confining magnetic field provided, i.e. the part of the entire or whole magnetic field provided by the magnetic elements 104a, 104b that confines the plasma in the deposition zone 114, is characterised by magnetic field lines that follow the curve of the curved path C.

Where the curve of the curved path C is referenced in certain examples, this can be understood as the degree to which the path along which the substrate guide 118 carries the substrate 116 is curved. For example, the curved member 118, such as a drum or roller, carries the substrate 116 along the curved path C. In such examples, the curve of the curved path C results from the degree to which the curved surface of the curved member 118 that carries the substrate 116 is curved, e.g. deviates from a flat plane. In other words, the curve of the curved path C may be understood as the degree to which the curved path C that the curved member 118 causes the substrate 116 to follow is curved. To substantially follow the curve of the curved path C may be understood as to substantially conform to or replicate the curved shape of the curved path C. For example, magnetic field lines may follow a curved path that has a common centre of curvature with the curved path C, but which has a different (in the illustrated examples larger) radius of curvature than the curved path C. For example, the magnetic field lines may follow a curved path that is substantially parallel to, but radially offset from, the curved path C of the substrate 116. In examples, the magnetic field lines follow a curved path that is substantially parallel to, but radially offset from, the curved surface of the curved member 118. For example, the magnetic field lines describing the confining magnetic field in FIG. 2 follow a curved path, at least in the sputter deposition zone 114, that is substantially parallel to, but radially offset from, the curved path C, and hence which substantially follows the curve of the curved path C.

The magnetic field lines describing the confining magnetic field may be arranged to follow the curve of the curved path C around a substantial or significant sector or portion of the curved path C. For example, the magnetic field lines may follow the curve of the curved path C over all or a substantial part of the notional sector of the curved path C, over which the substrate 116 is guided by the curved member 118. In examples, the curved path C represents a portion of a circumference of a notional circle, and magnetic field lines characterising the confining magnetic field are arranged to follow the curve of the curved path C around at least about 1/16 or at least about ⅛ or at least about ¼ or at least about ½ of the circumference of the notional circle.

In examples where the substrate guide 118 is provided by a curved member or drum, such as that of FIGS. 1 and 2, the magnetic field lines characterising the confining magnetic field is arranged to follow a curve of the curved member around a substantial or significant sector or portion of the curved member, for example over all or a substantial part of the notional sector of the curved member that carries or contacts the web of substrate 116 in use. For example, the curved member may be substantially cylindrical in shape, and magnetic field lines characterising the confining magnetic field may be arranged to follow the curve of the curved member around at least about 1/16 or at least about ⅛ or at least about ¼ or at least about ½ of the circumference of the curved member. In FIG. 2, the magnetic field lines characterising the confining magnetic field follow a curved path around about at least ¼ of the circumference of the substrate guide 118, which in this example includes a curved member (which in this case is formed by the surface of a drum).

It will be appreciated that magnetic field lines may be used to describe the arrangement or geometry of a magnetic field. An example magnetic field provided by the example magnetic elements 104a, 104b, 104c is illustrated schematically in FIGS. 2 and 4, where magnetic field lines (indicated as is convention by arrowed lines) are used to describe the magnetic field provided in use. As mentioned, there are some magnetic field lines which do not substantially follow the curvature of the curved member, but the confining magnetic field, i.e. that which confines the plasma 112 into the deposition zone 114, is characterised by magnetic field lines arranged to follow the curve of the curved path C. As best seen in FIGS. 2 and 4, the magnetic field lines characterising the confining magnetic field are each curved so as to, at least in the deposition zone 114, substantially follow the curve of the curved path C.

The magnetic field lines being arranged to follow the curve of the curved path C of the substrate 116 confines the generated plasma 112 around the curve of the curved path C into the deposition zone 114. This occurs because the generated plasma 112 tends to follow the magnetic field lines. For example, ions of the plasma within the confining magnetic field and with some initial velocity will experience a Lorentz force that causes the ion to follow a periodic motion around the magnetic field line. If the initial motion is not strictly perpendicular to the magnetic field, the ion follows a helical path centred on the magnetic field line. The plasma containing such ions therefore tends to follow the magnetic field lines and hence is confined on a path defined thereby. Accordingly, since the magnetic field lines are arranged to substantially follow a curve of the curved path C, the plasma 112 will be confined so as to substantially follow a curve of the curved path C, and hence be confined around the curve of the curved path C into the deposition zone 114.

Confining the generated plasma 112 to substantially conform to a curvature of at least part of a curved surface of the curved member 118, e.g. follow a curve of the curved path C, allows for more uniform distribution of plasma density at the substrate 116 at least in a direction around the curved surface of the curved member 118, e.g. the curve of the curved path C. This in turn allows for a more uniform sputter deposition onto the substrate 116 in a direction around the curved member 118, e.g. the curved path C. The sputter deposition may therefore, in turn, be performed more consistently. This can improve the consistency of the processed substrate and reduce the need for quality control compared to, e.g., magnetron type sputter deposition apparatuses where the magnetic field lines describing the magnetic field produced thereby loop tightly into and out of a substrate, and hence do not allow for uniform distribution of plasma density at the substrate.

Alternatively, or additionally, confining the generated plasma 112 to substantially conform to a curvature of at least part of a curved surface of the curved member 118, e.g. follow a curve of the curved path C, allows for an increased area of the substrate 116 to be exposed to the plasma 112, and hence for an increased area in which sputter deposition may be effected. This allows for the substrate 116 to be fed through a reel-to-reel type apparatus at a faster rate for a given degree of deposition, and hence allow for more efficient sputter deposition.

In some examples, such as that of FIGS. 1 and 2, the magnet arrangement (or “magnetic confining arrangement”) 104 comprises at least two magnetic elements 104a, 104b arranged to provide a magnetic field. In some cases, the at least two magnetic elements 104a, 104b are arranged such that a region of relatively high magnetic field strength defined between the at least two magnetic elements 104a, 104b is in the form of a sheet. The magnet arrangement 104 in such cases is configured to confine the plasma 112 in the form of a sheet, that is, in a form in which the depth (or thickness) of the plasma 112 is substantially less than its length or width. The thickness of the sheet of plasma 112 may be substantially constant along the length and width of the sheet. The density of the sheet of plasma 112 may be substantially uniform in one or both of its width and length directions.

In some examples, a region of relatively high magnetic field strength provided between the at least two magnetic elements 104a, 104b substantially conforms to the curvature of at least part of the curved surface of the curved member 118, e.g. substantially follows the curve of the curved path C.

In the example illustrated schematically in FIGS. 1 and 2, two magnetic elements 104a, 104b are located on opposite sides of the drum 118 to one another, and each is disposed above a lowermost portion of the drum 118 (in the sense of FIG. 1).

The two magnetic elements 104a, 104b confine the plasma 112 to conform to the curvature of at least part of the curved surface of the curved member 118, e.g. to follow the curve of the curved path C, on both sides of the curved member 118. In FIGS. 1 and 2, the plasma 112 follows the curve of the curved path C on a feed-on side, where the substrate 116 is fed onto the curved member 118, and a feed-off side where the substrate 116 is fed off of the curved member 118. Having at least two magnetic elements therefore provides for a (further) increase in the area of the substrate 116 that is exposed to plasma 112 in the sputter deposition zone 114, and hence increased area in which sputter deposition may be effected. This allows the substrate 116 to be fed through a reel-to-reel type apparatus at a (still) faster rate for a given degree of deposition, and hence allows more efficient sputter deposition, for example.

In some examples, one or more of the magnetic elements 104a, 104b is an electromagnet 104a, 104b. The apparatus 100 comprises a controller (not shown) in some cases to control a magnetic field strength of, e.g. provided by, one or more of the electromagnets 104a, 104b. This allows the arrangement of the magnetic field lines describing the confining magnetic field to be controlled. In turn, the plasma density at the substrate 116 and/or the target material 108 within the sputter deposition zone 114 can be adjusted, and hence control over the sputter deposition can be improved. This can in turn allow for improved flexibility in the operation of the sputter deposition apparatus 100.

In some examples, one or more of the magnetic elements 104a, 104b is provided by a solenoid 104a, 104b. In examples, the solenoid 104a, 104b is elongate in cross section. For example, the solenoid 104a, 104b may be elongate in cross section in a direction substantially parallel to an axis of rotation of the curved member 118, e.g. roller 118. Each solenoid 104a, 104b may define an opening through which plasma 112 passes (is confined) in use. As per the example illustrated schematically in FIGS. 1 and 2, there are three solenoids 104a, 104b and each solenoid 104a, 104b is angled so that a region of relatively high magnetic field strength is provided between the solenoids 104a, 104b, e.g. to substantially follow the curve of the curved path C. In such a way, as illustrated in FIG. 1, the generated plasma 112 passes through a first of the solenoids 104a, under the drum 118 (in the sense of FIG. 1) into the deposition zone 114, and up towards and through the second of the solenoids 104b.

Although only two magnetic elements 104a, 104b are shown in FIGS. 1 and 2, it will be appreciated that further magnetic elements (not shown), e.g. further such solenoids, may be placed along the path of the plasma 112. This can allow for strengthening of the confining magnetic field and hence for precise confining of the plasma. Additionally, or alternatively, this can allow for more degrees of freedom in the control of the confining magnetic field.

In some examples, such as that of FIGS. 1 and 2, the magnet arrangement 104, e.g. comprising one or more magnetic elements 104a, 104b, is configured to confine the plasma 112 in the form of a sheet. For example, the magnet arrangement 104 is arranged to provide the magnetic field to confine the plasma 112 in the form of a sheet. In some examples, the magnet arrangement 104 is configured to confine the plasma 112 in the form of a sheet having a substantially uniform density, e.g. at least in the deposition zone 114. In certain cases, the magnet arrangement 104 is configured to confine the plasma 112 in the form of a curved sheet.

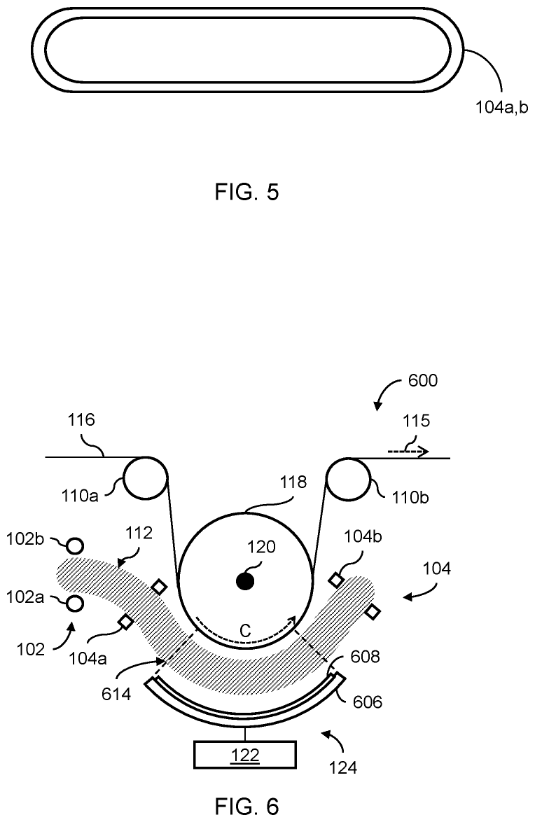

For example, as illustrated in FIGS. 4 and 5, in some examples one or more of the solenoids 104a, 104b is elongate in a direction substantially perpendicular to a direction of the magnetic field lines produced internally thereof in use. For example, as perhaps best seen in FIGS. 3 to 5, the solenoids 104a, 104b each have an opening via which plasma 112 is confined in use (through which plasma 112 passes in use), where the opening is elongate in a direction substantially parallel to a longitudinal axis 120 of the curved member 118. As perhaps best seen in FIGS. 3 and 4, the elongate antennae 102a, 102b extend parallel to and in line with the solenoids 104a, 104b. As described above, plasma 112 may be generated along the length of the elongate antennae 102a, 102b, and the elongate solenoid 104a confines, e.g. guides, the plasma 112 in a direction away from the elongate antennae 102a, 102b, and through the elongate solenoid 104a.

The plasma 112 in this example is confined, e.g. guided, from the elongate antennae 102a, 102b by the elongate solenoid 104a in the form of a sheet. That is, in a form in which the depth (or thickness) of the plasma 112 is substantially less than its length or width. The thickness of the sheet of plasma 112 may be substantially constant along the length and width of the sheet. The density of the sheet of plasma 112 may be substantially uniform in one or both of its width and length directions. The plasma 112, in the form of a sheet, is confined in this case by the magnetic field provided by the solenoids 104a, 104b around the curved member 118 so as to substantially conform to the curvature of a curved surface of the curved member 118, e.g. follow the curve of the curved path C, into the deposition zone 114. The plasma 112 is thereby confined in the form of a curved sheet in this example. The thickness of such a curved sheet of plasma 112 may be substantially constant along the length and width of the curved sheet. The plasma 112 in the form of a curved sheet may have a substantially uniform density, for example the density of the plasma 112 in the form of a curved sheet is substantially uniform in one or both of its length and width.

Confining the plasma in the form of a curved sheet allows for an increased area of the substrate 116 carried by the curved member 118 to be exposed to the plasma 112, and hence for an increased area in which sputter deposition may be effected. This allows the substrate 116 to be fed through a reel-to-reel type apparatus at a (still) faster rate for a given degree of deposition, and hence provides for more efficient sputter deposition.

Confining the plasma 112 in the form of a curved sheet, for example a curved sheet having a substantially uniform density (e.g. at least in the sputter deposition zone 114) alternatively or additionally allows for a more uniform distribution of plasma density at the substrate 116, e.g. in both of a direction around the curve of the curved member 118, and over the length of the curved member 118. This in turn allows for a more uniform sputter deposition onto the substrate 116, e.g. in a direction around the surface of the curved member 118 and across the width of the substrate 116. The sputter deposition can therefore, in turn, be performed more consistently. The consistency of the processed substrate can thus be improved, and the need for quality control reduced, compared to, for example, magnetron type sputter deposition apparatuses where the magnetic field lines characterising the magnetic field produced thereby loop tightly into and out of a substrate, and hence do not allow to provide uniform distribution of plasma density at the substrate.

In some examples, the confined plasma 112 is, at least in the deposition zone 114, high density plasma. For example, the confined plasma 112 (in the form of a curved sheet or otherwise) has, at least in the deposition zone 114, a density of 10¹¹ cm⁻³ or more. Plasma 112 of high density in the deposition zone 114 allows for effective and/or high rate sputter deposition.

The target assembly 124 of FIGS. 1 and 2 also includes biasing means 122 for applying electrical bias to the target material 108. Electrical bias for example refers to a voltage applied to the target material 108. In the example of FIGS. 1 and 2, the biasing means 122 is configured to apply electrical bias comprising a direct current (DC) voltage to the target material 108. The DC voltage may be a negative polarity voltage, with a value which is less than zero. The biasing means 122 in this case has a first terminal (not shown) at a first electric potential and a second terminal (not shown) at a second, different, electric potential, such that a difference between the first electric potential and the second electric potential corresponds to the voltage to be applied to the target material 108. In this case, the first terminal is electrically connected to the target material 108 and the second terminal is electrically connected to ground, to apply the voltage to the target material 108.

By applying the electrical bias to the target material 108, ions of a plasma 112 are attracted towards the target material 108. This increases interactions between the plasma 112 and the target material 108, which can increase the rate at which particles of the target material 108 are ejected by the plasma 112. Increasing the rate of ejection of the particles of target material 108 typically increases the rate at which these particles are deposited on the substrate 116, increasing the rate of sputter deposition of the target material 108. By applying the electrical bias to the target material 108 in the apparatus 100 according to examples herein, in which plasma is configured around a curve of a curved path along which the substrate 116 is guided, the target material 108 is deposited in a compact, efficient matter, with increased uniformity on the substrate 116.

By controlling the electrical bias applied to the target material 108, the rate at which sputter deposition of the target material 108 occurs can be controlled, which can be used to deposit a particular pattern of target material 108 on the substrate 116.

In an illustrative example, it is desired to deposit patches of target material 108 of different respective thickness on the substrate 116, in order to create a particular pattern of target material 108 on the substrate 116. This can be performed straightforwardly using the apparatus 100 by applying an electrical bias with a first magnitude at a first time during which a first portion of the substrate 116 is conveyed through the deposition zone 114, to deposit a first patch of target material 108 with a first thickness on the first portion of the substrate 116. Subsequently, at a second time during which a second portion of the substrate 116 is conveyed through the deposition zone 114, an electrical bias with a second magnitude less than the first magnitude is applied. This causes a second patch of target material 108 with a second thickness less than the first thickness to be deposited on the second portion of the substrate 116. This is due to the decrease in magnitude of the electrical bias at the second time (during which time the second patch of target material 108 is sputter deposition), which in this example decreases the rate of sputter deposition. It is to be appreciated that this is merely an example, though, and control of the electrical bias may be performed in various different ways to straightforwardly and efficiently deposit a particular pattern of target material 108 on the substrate 116.

Control of the electrical bias applied to the target material 108 by the biasing materials 122 can also or instead be used to control the crystallinity of the target material 108 deposited on the substrate 116. Crystallinity of a material generally refers to the degree of structural order in a material, e.g. the extent to which the atoms and molecules of the material are arranged in a regular, periodic pattern. The crystallinity may be measured using various techniques, such as X-ray crystallography techniques or Raman spectroscopy. The crystallinity typically depends on, and in some cases may be defined by, the crystallite size, which may be measured using X-ray diffraction. The crystallite size can be calculated from an X-ray diffraction pattern using the Scherrer equation. The Scherrer equation states that the crystallite size, r, of a material is given by:

$$τ = \frac{K λ}{β cos θ}$$

where τ is the crystallite size, which may be taken as the mean size of ordered (crystalline) domains of the material and which may be smaller or equal to a gain size of the material, K is a dimensionless shape factor, λ is the X-ray wavelength, β is the line broadening of a peak in the X-ray diffraction pattern in radians (after subtracting instrumental line broadening), and θ is the Bragg angle.

In some cases, the biasing means 122 is configured to apply the electrical bias to the target material 108 at a first power value, and the plasma generation arrangement is configured to generate the plasma at a second power value. If a ratio of the second power value to the first power value is less than or equal to one, the target material 108 deposited on the substrate 116 tends to have an amorphous structure, with relatively little or no structural order as measured using e.g. X-ray diffraction or Raman spectroscopy. A material may be considered to have an amorphous structure where the material is non-crystalline, such that atoms of the material do not form a crystal lattice. If, however, the ratio of the second power value to the first power value is greater than one, the target material 108 deposited on the substrate 116 generally has an at least partially ordered structure, and may have a crystalline structure, in which atoms of the deposited material form a crystal lattice in at least one region of the material and in some cases throughout the entire material. On this basis, by appropriately controlling the ratio of the second power value to the first power value, the structure of the target material 108 as deposited on the substrate 116 can be straightforwardly controlled.

For example, by controlling this ratio to have a value of greater than one, target material 108 with a crystalline structure can be deposited on the substrate 116 without undergoing subsequent post-processing steps such as annealing. This simplifies deposition of crystalline materials. In some cases, the structure of the deposited target material 108 is independent of the substrate 116 onto which the target material 108 is deposited. In these cases, an at least partially ordered, and e.g. crystalline, target material 108 may be deposited irrespective of the substrate 116 by providing the ratio with a value of greater than one. The apparatus 100 therefore provides flexibility for deposition of target material 108 with an ordered structure onto substrates of various different types, and for various different purposes.

Increasing the ratio of the second power value to the first power value tends to increase the order in the structure of the target material 108 deposited on the substrate 116. Hence, the structure of the target material 108 deposited on the substrate 116 can be accurately controlled in a simple manner, by control of this ratio.

At least a portion of and in some cases all of the deposited target material 108 may have a hexagonal crystal structure. A crystal structure of the deposited target material 108, which may be LiCoO₂, may be in the R3̅m space group. The R3̅m space group structure is a layered structure, and may be a layered oxide structure, e.g. where the target material 108 is LiCoO₂. This structure has a number of benefits, such as having a high usable capacity and high speed of charging and discharging compared to a low energy structure (which is in the Fd3m space group for LiCoO₂). The R3̅m space group is regarded as having better performance in typical battery applications due to enhanced reversibility and fewer structural changes on lithium intercalation and deintercalation. Therefore depositing crystalline LiCoO₂ in the R3̅m space group as the deposited target material 108 is favoured for solid state battery applications. However, this is merely an example, and in other cases, e.g. for other applications, the deposited target material 108 may have a different chemical and/or crystal structure.

During deposition of the target material 108 on the substrate 116 with an at least partially ordered structure, crystals of the crystalline structure grow substantially epitaxially from the surface of the substrate in some cases. Epitaxial growth generally refers to a type of crystal growth in which new crystalline layers are formed with a well-defined orientation with respect to a crystalline structure of the material. Substantially epitaxial growth for example refers to deposition of a new layer, which itself includes at least one crystalline region, such that a substantial proportion (e.g. at least 70%, 80%, 90% or more) of the at least one crystalline region of the new layer has the same orientation with respect to the substrate 116 on which the material is deposited. Epitaxial growth tends to allow lithium ions to intercalate and deintercalate more easily. On this basis, target material 108 comprising lithium can be deposited on a substrate 116 substantially epitaxially using the apparatus 100 described herein to improve intercalation and deintercalation of the lithium ions. This allows the apparatus 100 to be used for deposition of such target material, e.g. for the production of solid-state batteries.

The crystals of an at least partially ordered target material 108 deposited on the substrate 116 may be aligned with the (101) and (110) planes. The (101) and (110) planes are lattice planes of a crystalline structure of the target material 108, and are expressed as Miller indices, as the skilled person will appreciate. In examples, the (101) and (110) planes are substantially parallel to the substrate, such as parallel within manufacturing or measurement tolerances. Depositing the target material 108 on the substrate 116 with such a structure for example provides the deposited target material 108 with suitable properties for various different applications.

The ratio of the second power value to the first power value is less than 3.5 in some cases. For example, the ratio may lie in a range between 1 and 3.5. With such a ratio, the target material 108 is deposited on the substrate 116 with an at least partially ordered structure, such as a crystalline structure. The at least partially ordered structure of the target material 108 is obtained by the sputter deposition of the target material 108 in such cases, without requiring further process steps such as annealing. Target material 108 with such a structure can therefore be deposited more straightforwardly and/or efficiently than otherwise.

The first power value is at least one watt per square centimetre (1 W cm⁻²) in some examples. The first power value is at most fifteen watts per square centimetre (15 W cm⁻²) in some cases, e.g. where the target material 108 comprises a ceramic or oxide. In other cases, the first power value is at most seventy watts per square centimetre (70 W cm⁻²) e.g. for metallic target materials 108 such as lithium, cobalt, or alloys thereof. In further cases, the first power value is up to one hundred watts per square centimetre (100 W cm⁻²) e.g. for other target materials 108.

The actual power in the plasma may be less than the power used to generate the plasma (where the power used to generate the plasma is referred to herein as the second power value). In this regard, the efficiency of the generation of the plasma (defined as the actual power in the plasma divided by the power used to generate the plasma multiplied by 100) may be from 50% to 85%, typically about 50%.

During steady-state performance of the sputter deposition (in which electrical energy supplied to the apparatus 100 for performing the sputter deposition is, within a margin of error, the same as the energy consumed by the apparatus 100), the fraction of (P_{P}*E_{PT})/(P_{T}*E_{PP}) may be greater than 1, optionally in the range of 1 to 4, possibly in the range of 1 to 3, and in certain embodiments between 1 and 2. In this fraction, P_{P}=the average use of plasma energy (in Watts), P_{T}=the power associated with the bias on the target (referred to herein as the first power value), E_{PP} is a fraction (<1) representative of a measure of the efficiency of plasma generation and E_{PT} is a fraction (<1) representative of a measure of the efficiency of the supply of electrical energy to the target(s). The efficiency, E_{PP}, of the generation of the plasma may be calculated as the actual power in the plasma divided by the power used to generate the plasma. The efficiency, E_{PT}, of the supply of electrical energy to the target(s) may be calculated as the actual power delivered divided by the electrical power used. In typical set-ups it may be assumed that E_{PT}=1. It is preferred that E_{PT}>0.9.

During steady-state performance of the sputter deposition, the normalised power ratio parameter, PRP_{N}, may be greater than 1, optionally in the range of 1 to 4, possibly in the range of 1 to 3, and in certain cases between 1 and 2 (where PRP_{N}=N*Pp/P_{T} and where N is a normalising factor, which may satisfy 1.2<N<2, or may simply be N=1.7). During steady-state performance of the sputter deposition, the power ratio parameter, PRP (where PRP=P_{P}/P_{T}), may be greater than 0.5, optionally in the range of 0.5 to 2, possibly in the range of 0.6 to 1.5, and in certain cases between 0.6 and 1. These PRP_{N} and PRP values provide for effective and efficient sputter deposition of target material 108 on a substrate 116.

In the examples illustrated in FIGS. 1 to 5, the target portion 106 and the target material 108 supported thereby is substantially planar. However, in some examples (as described in more detail below) the target portion may be arranged, or may be configurable to be arranged, such that at least one part of the target portion defines a supporting surface forming an obtuse angle with respect to a supporting surface of another part of the target portion. For example, the target portion may be substantially curved. For example, the target portion may be arranged to substantially follow the curve of the curved path C.

FIG. 6 illustrates such an example apparatus 600. Many of the illustrated components of the apparatus 600 are the same as those of the apparatus 100 illustrated in FIGS. 1 to 5 and described above and will not be described again. Like features are given like reference signs, and it will be appreciated that any feature of the examples described with reference to FIGS. 1 to 5 may be applied to the example illustrated in FIG. 6. However, in the example illustrated in FIG. 6, the target portion 606 of the target assembly 124 is substantially curved. The target material 608 supported by the target portion 606 is accordingly substantially curved in this example. In this case, any one part of the curved target portion 606 forms an obtuse angle with any other part of the curved target portion 606 along the direction of the curve. In some examples, different parts of the target portion 606 may support different target materials, for example to provide for a desired arrangement or composition of deposition to the web of substrate 116.

In the example of FIG. 6, the curved target portion 606 substantially follows the curve of the curved path C. In this way, the curved target portion 606 substantially conforms to, and replicates, the curved shape of the curved path C. In FIG. 6, the curved target portion 606 has a curve that is substantially parallel to but radially offset from the curved path. In this case, the curve target portion 606 has a curve that has a common centre of curvature to the curved path C, but a different (larger in this case) radius of curvature to the curved path C. Accordingly, the curved target portion 606 in turn substantially follows the curve of the curved plasma 112 confined around the curved member 118 in use. Put another way, in some examples, such as that of FIG. 6, the plasma 112 may be confined by the magnetic elements 104a, 104b of the confining arrangement to be located between the path C of the substrate 116 and the target portion 606, and substantially follow the curve of both the curved path C and the curved target portion 606.

As for the target portion 108 of the apparatus 100 illustrated in FIGS. 1 to 5, it will be appreciated that the example target portion 606 of FIG. 6 (and accordingly the target material 608 supported thereby) may extend substantially across an entire length of the curved member 118 (e.g. in a direction parallel with the longitudinal axis 120 of the drum 118). This maximises the surface area of the substrate 116 carried by the drum 118 onto which target material 608 may be deposited.

As mentioned, the plasma 112 of FIG. 6 is confined to substantially follow the curve of both the curved path C and the curved target portion 606. The area or volume between the curved path C and the curved target portion 606 is accordingly curved around the curved member 118 in this example. The deposition zone 614 of FIG. 6 therefore represents a curved volume in which sputter deposition of the target material 608 to the substrate 116 carried by the curved member 118 occurs in use. This allows for an increase of the surface area of the substrate 116 carried by the curved member 118 present in the deposition zone 614 at any one time. This in turn allows for an increase in the surface area of the substrate 116 onto which target material 608 may be deposited in use. This in turn allows for an increased area in which sputter deposition may be effected, but without substantially increasing the spatial footprint of the target portion 606, and without altering the dimensions of the curved member 118. This allows, for example, for the web of substrate 116 to be fed through a reel-to-reel type apparatus at a (still) faster rate for a given degree of deposition, and hence for more efficient sputter deposition, but also in a space efficient way.

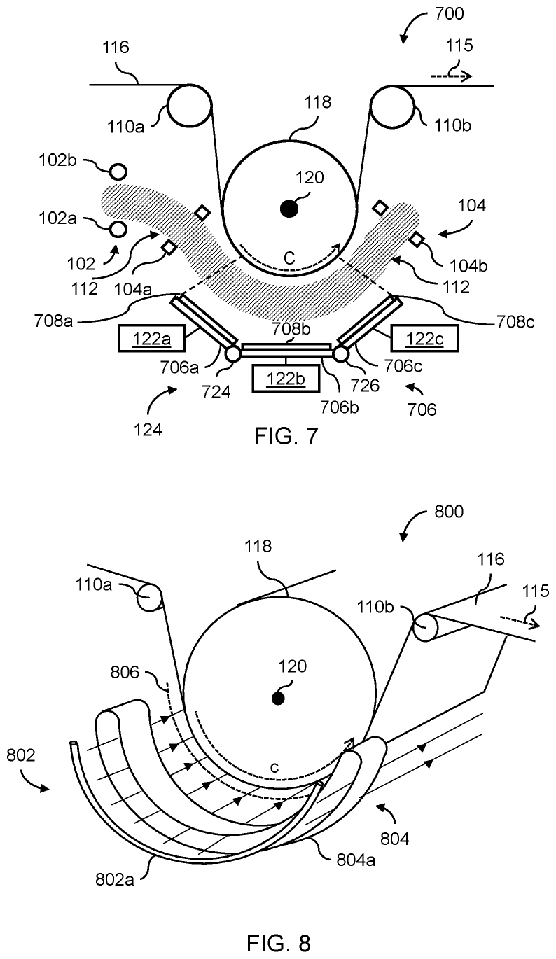

FIG. 7 illustrates an example apparatus 700. Many of the illustrated components of the apparatus 700 are the same as those of the apparatuses 100, 700 illustrated in FIGS. 1 to 6 and described above and will not be described again. Like features are given like reference signs, and it will be appreciated that any feature of the examples described with reference to FIGS. 1 to 6 may be applied to the example illustrated in FIG. 7. However, in the example illustrated in FIG. 7, the target portion 706 of the target assembly 124 is arranged, or configurable to be arranged, such that at least one part 706a of the target portion 706 defines a surface forming an obtuse angle with respect to a surface of another part 706b of the target portion 706.

In some examples, an angle that a first part 706a of the target portion 706 makes with a second, for example adjacent, part 706b of the target portion 706 is fixed at an obtuse angle. The obtuse angle may be chosen such that the first part 706a and the second part 706b together are arranged so as to approximate the curve of the curved path C. In FIG. 7, the target portion 706 comprises three (substantially planar as illustrated in FIG. 7) parts 706a, 706b, 706c with each part making an obtuse angle with respect an adjacent part, although this is merely an example. A first part 706a is be disposed towards the feed-in side of the curved path C, a second part 706b is disposed towards a central portion of the curved path C, and a third part 706c is disposed towards a feed-off side of the curved path C. The three parts 706a, 706b, 706c together are arranged so as to approximate the curve of the curved path C. The deposition zone 714 therefore approximates a curved volume in which sputter deposition of the target material 708a, 708b, 708c to the substrate 116 occurs in use. An increase of the surface area of the web of substrate 116 present in the deposition zone 714 at any one time is thereby increased. This allows for an increased area in which sputter deposition may be effected, but without substantially increasing the spatial footprint of the target portion 706, and without altering the dimensions of the curved member 118, for example.

In some examples, an angle that a first part 706a of the target portion 706 makes with a second, for example adjacent, part 706b of the target portion 706 is configurable. For example, the first part 706a and the second part 706b may be mechanically connected by a hinge element 724 or other such component that allows the angle between the first part 706a and the second part 706b to be changed. Similarly, the second part 706b and the third part 706c may be mechanically connected by a hinge element 726 or other such component that allows the angle between the second part 706b and the third part 706c to be changed. An actuator and suitable controller (not shown) may be provided to move the first part 706a and/or the third part 706c relative to the second part 706b, that is to alter the angle made between the first part 706a and/or the third part 706c relative to the second part 706b. This allows for control of the plasma density experienced by the target material 708a, 708c of the first part 706a or third part 706c of the target portion, and hence allows for control of the deposition rate in use.

Alternatively or additionally, the confining magnetic field provided by the magnetic elements 104a, 104b may be controlled by a controller (not shown) to alter the curvature of the plasma 112 and thereby control the density of plasma experienced by the target material 708a, 708b, 708c of the first part 706a, second part 706b, or third part 706c of the target portion, and hence allow for control in the deposition rate in use.

In some examples, the target material provided on one part 706a, 706b, 706c of the target portion 700 is different to the target material provided on another part 706a, 706b, 706c of the target portion. This can allow for a desired arrangement or composition of target material to be sputter deposited onto the web of substrate 116. Control of the plasma density experienced by one or more of the target portions 706a, 706b, 706c, for example by control of the angle that the first part 706a or third part 706c makes with the second part 706b, and/or by control of the curvature of the confined plasma via control of the magnetic elements 104a, 104b, can allow for control of the type or composition of target material that is sputter deposited onto the web of substrate 116. This allows for flexible sputter deposition.

In the example of FIG. 7, the biasing means 122a, 122b, 122c are configured to apply electrical bias independently to one or more respective target materials of the plural target materials 708a, 708b, 708c. In FIG. 7, there is a respective biasing means 122a, 122b, 122c for each of the respective target materials 708a, 708b, 708c. For example, each of the biasing means 122a, 122b, 122c may be a separate DC voltage source. In other cases, a single biasing means is configured to apply electrical bias to multiple target materials but is configured to control the electrical bias applied to each target material independently.

In this example, the rate at which each of the respective target materials 708a, 708b, 708c is also independently controllable by controlling the electrical bias applied by the biasing means 122a, 122b, 122c to each of the respective target materials 708a, 708b, 708c. This allows a greater amount of one of the target materials 708a, 708b, 708c to be ejected than another. This improves the flexibility of the apparatus 100, as it allows the apparatus 100 to be used to deposit different respective proportions of each of the respective target materials 708a, 708b, 708c on the substrate 116. For example, a greater amount of the first target material 708a than the second and third target materials 708b, 708c can be deposited on the substrate 116 by applying an electrical bias with a greater magnitude using the first biasing means 122a than that applied using the second and third biasing means 122b, 122c.

The electrical bias applied by the biasing means 122a, 122b, 122c is, in this example, controllable over time. This further increases the flexibility of the apparatus 600, as it allows the apparatus 600 to be used to deposit different combinations of the target materials 708a, 708b, 708c over time. Furthermore, due to the independent control of the electrical bias applied to each of the target materials 708a, 708b, 708c, a pattern of the target materials 708a, 708b, 708c deposited on the substrate 116 can in turn be controlled. This allows the apparatus 600 to be used to deposit a desired pattern on the substrate 116 in a simple and efficient manner.

In the examples illustrated in FIGS. 1 to 7, the magnetic field lines characterising the confining magnetic field are each curved so as to, at least in the deposition zone 114, substantially follow the curve of the curved path C. However, this need not necessarily be the case and in other arrangements the confining magnetic field is characterised by magnetic field lines arranged to, at least in the deposition zone 114, substantially follow a curve of the curved path C so as to confine the plasma 112 around the curve of the curved path C. For example, in some cases, the magnetic field lines characterising the confining magnetic field are arranged such that an imaginary line, extending perpendicularly to each magnetic field line and connecting the magnetic field lines, is curved so as to, at least in the deposition zone, substantially follow the curve of the curved path C.

FIG. 8 illustrates an example of an apparatus 800 with such a magnetic field. Many of the illustrated components of the apparatus 800 are the same as those of the apparatuses 100, 600, 700 illustrated in FIGS. 1 to 7 and described above and will not be described again. Like features are given like reference signs, and it will be appreciated that any feature of the examples described with reference to FIGS. 1 to 7 may be applied to the example illustrated in FIG. 8. However, in the example illustrated in FIG. 8, a magnetic element 804a of a magnetic confining arrangement 804 is arranged to provide a confining magnetic field, wherein the magnetic field lines (black arrows in FIG. 8) characterising the confining magnetic field are each themselves substantially straight but are arranged such that an imaginary line 806, extending perpendicularly to each magnetic field line and connecting the magnetic field lines, is curved so as to, at least in the deposition zone (not indicated explicitly in FIG. 8 for clarity), substantially follow the curve of the curved path C.

In this example, the plasma generation arrangement 802 comprises an elongate antenna 802a that is curved and extends in a direction substantially perpendicular to a longitudinal axis 120 of the curved member or drum 118. In the example of FIG. 8, the longitudinal axis 120 of the curved member 118 is also the rotation axis of the curved member 118. Only one antenna 802a is shown in FIG. 8 for clarity but it will be appreciated that more than one such antennae 802a may be used. The curved antenna 802a of FIG. 8 substantially follows the curve of the curved path C, and in this case is parallel to, but radially and axially offset from, the curved path C due to being radially and axially offset from the curved surface of the curved member 118 that guides the substrate along the curved path C. The curved antenna 802a may be driven with radio frequency power to produce plasma (not shown in FIG. 8 for clarity) having a substantially curved shape.

The magnetic element 804a in FIG. 8 comprises a solenoid 804a. Only one magnetic element 804a is shown in FIG. 8 for clarity, but it will be appreciated that, for example, another such magnetic element (not shown) may be placed on the opposite side of the curved member 118 to the solenoid 804a in the sense of FIG. 8. The solenoid 804a has an opening through which plasma (not shown in FIG. 8) is confined in use. The opening may be curved and elongate in a direction substantially perpendicular to the longitudinal axis (rotational axis) 120 of the curved member 118. The curved solenoid 804a in this example substantially follows the curve of the curved path C, and is parallel to, but radially and axially offset from, the curved surface of the curved member 118. In FIG. 8, the curved solenoid 804a is disposed intermediate of the curved antenna 802a and the curved member 118. The curved solenoid 804a provides a confining magnetic field in which the field lines are arranged such that an imaginary line 806, extending perpendicularly to each magnetic field line and connecting the magnetic field lines, is curved so as to, at least in the deposition zone, substantially follow the curve of the curved path C.

Plasma (not shown in FIG. 8) is generated along the length of the curved antenna 802a, and the curved solenoid 804a confines the plasma in a direction away from the curved antenna 802a and through the curved solenoid 804a. The plasma is confined by the curved solenoid 804a in the form of a curved sheet in examples such as that of FIG. 8. In this case, the length of the curved sheet extends in a direction parallel to the longitudinal (rotational) axis 120 of the curved member 118. The plasma, in the form of a curved sheet, is confined by the magnetic field provided by the solenoid 804a around the curved member 118 and so as to replicate the curve of the curved member 118. The thickness of the curved sheet of plasma may be substantially constant along the length and width of the curved sheet. The plasma in the form of a curved sheet may have a substantially uniform density, for example the density of the plasma in the form of a curved sheet may be substantially uniform in one or both of its length and width. As described above, the plasma being confined in the form of a curved sheet allows for an increased area in which sputter deposition is effected and hence for more efficient sputter deposition, and/or for a more uniform distribution of plasma density at the substrate 116, e.g. in both of a direction around the curve of the curved member, and across the width of the substrate 116. This in turn allows for a more uniform sputter deposition onto the substrate 116, e.g. in a direction around the surface of the curved member and across the length of the curved member 118, which can improve the consistency of the processing of the substrate.

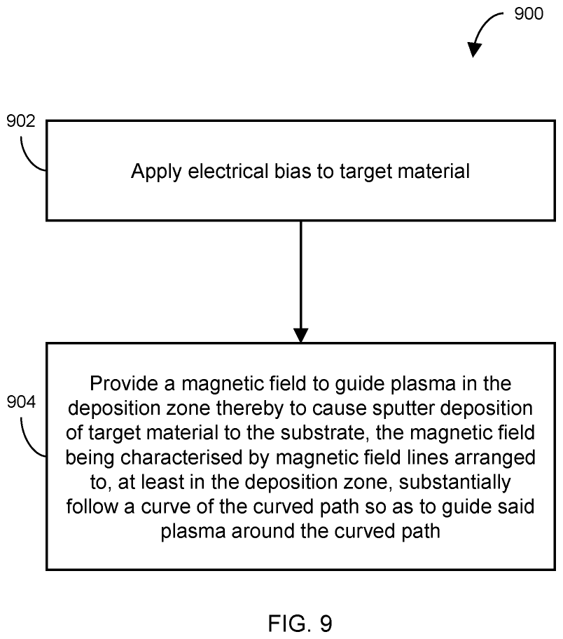

Referring to FIG. 9, there is illustrated schematically an example method of sputter deposition of target material 108, 608, 708a, 708b, 708c to a substrate 116. In the method, the substrate 116 is guided by a substrate guide 118 along a curved path C. A deposition zone 114, 614, 714 is defined between the substrate guide 118 and a target portion 106, 606, 706a, 706b, 706c supporting the target material 108, 608, 708a, 708b, 708c. The target material 108, 608, 708a, 708b, 708c, the substrate 116, the deposition zone 114, 614, 714, the target portion 106, 606, 706a, 706b, 706c, the substrate guide 118 and/or the curved path C may be, for example, those of any of the examples described above with reference to FIGS. 1 to 8. In some examples, the method is performed by one of the apparatuses 100, 600, 700, 800 described with reference to FIGS. 1 to 8.

The method of FIG. 9 comprises, in step 902, providing applying electrical bias to the target material 108, 608, 708a, 708b, 708c. The electrical bias may be provided by the biasing means 122, 122a, 122b, 122c described above with reference to FIGS. 1 to 8.

In step 904, the method of FIG. 9 comprises providing a magnetic field to confine the plasma into the deposition zone 114, 614, 714 thereby to cause sputter deposition of target material 108, 608, 708a, 708b, 708c to the substrate 116. The magnetic field is characterised by magnetic field lines arranged to, at least in the deposition zone 114, 614, 714, substantially follow a curve of the curved path C so as to confine the plasma 112 around a curve of the curved path C For example, the plasma may be confined by one of the magnetic confining arrangements 104, 804 described above with reference to FIGS. 1 to 8.

As mentioned, confining the generated plasma 112 in this way allows for more uniform distribution of plasma density at the substrate 116 at least in a direction around curve of the curved path C. This in turn allows for a more uniform sputter deposition of the target material 108, 608, 708a, 708b, 708c onto the substrate 116 in a direction around the surface of the curved member 118. The sputter deposition can therefore, in turn, be performed more consistently. This can improve the consistency of the processed substrate and reduce the need for quality control. This may be as compared to, for example, magnetron type sputter deposition where the magnetic field lines characterising the magnetic field produced thereby loop tightly into and out of a substrate, and hence do not provide a uniform distribution of plasma density at the substrate.

Further, confining the generated plasma 112 so as to follow a curve of the curved path in this way can allow for an increased area of the substrate 116 to be exposed to the plasma 112, and hence for an increased area in which sputter deposition is effected. This can allow, for example, for the substrate 116, e.g. in the form of a web, to be fed through a reel-to-reel type apparatus at a faster rate for a given degree of deposition, and hence for more efficient sputter deposition.

The efficiency of the sputter deposition in examples in accordance with FIG. 9 is further increased by applying the electrical bias to the target material. This causes the plasma to be attracted towards the target material, increasing the sputtering rate. By appropriately controlling the electrical bias, the target material can be sputter deposited on a substrate with a desired structure, such as a crystalline structure, e.g. without requiring further post-processing steps. Sputter deposition in such cases is therefore further improved. Furthermore, flexibility is provided, as the method may be used to deposit a particular pattern of the target material on the substrate by control of the electrical bias, e.g. to deposit a greater amount of the target material on one portion of the substrate than another.

In examples, the method 900 includes providing the target material comprising at least one of lithium, cobalt, lithium oxide, cobalt oxide and lithium cobalt oxide. In such examples, the method 900 may be used for the production of various different components that include these materials, such as energy storage devices.

As discussed in detail with reference to FIGS. 1 to 5, in some examples in accordance with FIG. 9, step 902 includes applying the electrical bias at a first power value, and the method comprises generating a plasma at a second power value, such that a ratio of the second power value to the first power value is greater than 1. Such a ratio may be used to deposit the target material on the substrate with an at least partially ordered structure, such as a crystalline structure, in an efficient manner.

The above examples are to be understood as illustrative examples. It is to be understood that any feature described in relation to any one example may be used alone, or in combination with other features described, and may also be used in combination with one or more features of any other of the examples, or any combination of any other of the examples. Furthermore, equivalents and modifications not described above may also be employed within the scope of the accompanying claims.

1. A sputter deposition apparatus comprising:
a substrate guide arranged to guide a substrate along a curved path;
a target assembly comprising:
a target portion spaced from the substrate guide and arranged to support target material, the target portion and the substrate guide defining between them a deposition zone; and
biasing means for applying electrical bias to the target material; and
a confining arrangement comprising one or more magnetic elements arranged to provide a confining magnetic field to confine plasma in the deposition zone thereby to provide for sputter deposition of target material to the substrate in use, the confining magnetic field being characterised by magnetic field lines arranged to, at least in the deposition zone, substantially follow a curve of the curved path so as to confine said plasma around said curve of the curved path.

2. The apparatus according to claim 1, wherein the biasing means is configured to apply electrical bias having negative polarity to the target material.

3. The apparatus according to claim 1, wherein the biasing means is configured to apply electrical bias comprising a direct current voltage to the target material.

4. The apparatus according to claim 1, the apparatus further comprising a plasma generation arrangement configured to generate plasma.

5. The apparatus according to claim 4, wherein the biasing means is configured to apply the electrical bias to the target material at a first power value, and the plasma generation arrangement is configured to generate the plasma at a second power value, such that a ratio of the second power value to the first power value is greater than 1.

6. The apparatus according to claim 5, wherein the ratio of the second power value to the first power value is less than 3.5 or less than 1.5.

7. The apparatus according to claim 5, wherein the first power value is at least one watt per square centimetre, 1 W cm².

8. The apparatus according to claim 5, wherein the first power value is at most fifteen watts per square centimetre, 15 W cm⁻².

9. The apparatus according to claim 4, wherein the plasma generation arrangement comprises an inductively coupled plasma source.

10. The apparatus according to claim 4, wherein the plasma generation arrangement comprises one or more elongate antennae that extend in a direction substantially perpendicular to a longitudinal axis of the substrate guide.

11. The apparatus according to claim 4, wherein the plasma generation arrangement comprises one or more elongate antennae that extend in a direction substantially parallel to a longitudinal axis of the substrate guide.

12. The apparatus according to claim 1, wherein the target portion is arranged to support plural target materials and the biasing means is configured to apply electrical bias independently to one or more respective target materials of the plural target materials.

13. The apparatus according to claim 1, wherein the one or more magnetic elements are arranged to provide the confining magnetic field to confine plasma in the form of a curved sheet.

14. The apparatus according to claim 1, wherein the one or more magnetic elements are arranged to provide the confining magnetic field to confine plasma in the form of a curved sheet having, at least in the deposition zone, a substantially uniform density.

15. The apparatus according to claim 1, wherein one or more of the magnetic elements is an electromagnet.

16. The apparatus according to claim 15, wherein the apparatus comprises a controller arranged to control the magnetic field provided by one or more of the electromagnets.

17. The apparatus according to claim 1, wherein the confining arrangement comprises at least two of the magnetic elements arranged to provide the confining magnetic field.

18. The apparatus according to claim 17, wherein the at least two magnetic elements are arranged such that a region of relatively high magnetic field strength provided between the magnetic elements substantially follows the curve of the curved path.

19. The apparatus according to claim 1, wherein the target portion is arranged, or is configurable to be arranged, such that at least one part of the target portion defines a supporting surface forming an obtuse angle with respect to a supporting surface of another part of the target portion.

20. The apparatus according to claim 1, wherein the target portion is substantially curved.

21. The apparatus according to claim 1, wherein the target portion is arranged to substantially follow or approximate the curve of the curved path.

22. The apparatus according to claim 1, wherein the substrate guide is provided by a curved member that guides the substrate along the curved path.

23. A method of sputter deposition of target material to a substrate, the substrate being guided by a substrate guide along a curved path, wherein a deposition zone is defined between the substrate guide and a target portion supporting target material, the method comprising:
applying electrical bias to the target material; and
providing a magnetic field to confine plasma in the deposition zone thereby to cause sputter deposition of target material to the substrate, the magnetic field being characterised by magnetic field lines arranged to, at least in the deposition zone, substantially follow a curve of the curved path so as to confine said plasma around the curved path.

24. The method according to claim 23, comprising providing the target material comprising at least one of:
lithium;
cobalt;
lithium oxide;
cobalt oxide; and
lithium cobalt oxide.

25. The method according to claim 23, wherein applying the electrical bias to the target comprises applying the electrical bias at a first power value, and the method comprises generating a plasma at a second power value, such that a ratio of the second power value to the first power value is greater than 1.
